(19) United States
(12) Patent Application Publication
(10) Pub. No.: US 2007/0069634 A1
(43) Pub. Date: Mar. 29, 2007

(54) Method and system for patterning an organic light emitting diode display by printing

(75) Inventors: Amiram Carmon, Jerusalem (IL); Eli Vronsky, Ramat Hasharon (IL)

Correspondence Address: LOWE HAUPTMAN BERNER, LLP, 1700 DIAGONAL ROAD, SUITE 300, ALEXANDRIA, VA, 22314, US

(73) Assignee: PIXDRO LTD., Rosh Haayin (IL)

(21) Appl. No.: 10/596,098

(22) PCT Filed: Nov. 28, 2004
(86) PCT No.: PCT/IL04/01090

§ 371 Date: May 30, 2006

(30) Foreign Application Priority Data
Jan. 8, 2004 (IL) 159775
Jan. 8, 2004 (IL) 159774
Jan. 8, 2004 (IL) 159776
Nov. 28, 2003 (US) 60/525179

(51) Int. Cl. H05B 33/00; H01J 1/62

(52) U.S. Cl. 313/504; 313/510

(57) ABSTRACT

A device having a static image capable of self-illumination when activated, and comprising constituent pixels printed using a light emitting ink on a layer of an organic light emitting diode (OLED) device so as to form a pattern whose contour is determined only by the pixels and does not require pre-shaping of the layer. The pixels may be printed using ink jet technology on a layer of the OLED, such as the PEDOT layer or cathode of the OLED requiring only a single anode and cathode for activating all the pixels simultaneously thus avoiding a need for separate addressing of selected pixels. Colored pixels may be formed by using different colored light emitting inks.

### RELATED APPLICATIONS

The present application is National Phase of PCT Application Number PCT/IL2004/001090, filed Nov. 28, 2004, which claims priority of U.S. Provisional Application No. 60/525,179, filed Nov. 28, 2003, and Israeli Application Numbers 159774, 159775, and 159776, filed Jan. 8, 2004; the disclosures of all applications are incorporated by reference herein in their entirety.

### FIELD OF THE INVENTION

This invention relates to Organic Light Emitting Diodes (OLED).

### BACKGROUND OF THE INVENTION

Flat displays are now achieving the stage whereby they become a commodity. In large sized devices, most familiar is the LCD panel that substitutes for CRTs in computers, and plasma displays which substitute for CRTs in very large sized TV sets. There are also small instruments that use flat panels of the LCD type, for example mobile telephones and PDA's.

All these are based on the same patterning principle: the screen is divided into a matrix of sub millimetric picture elements (“pixels”) arranged along rows and columns which are electronically addressed according to the rows and columns in a “passive matrix”, or individually as is the case in “active matrix” displays. The addressing involves specialized electronics and software.

Such addressing is required to allow the displayed image to be changed and thus to be dynamic. In the case of LCDs, the pixelized structure is inherent in the display design. The same is true for plasma displays which are made of thousands of gas filled cells, which must be addressed individually.

A recent development in the field of displays is the so-called Organic Light Emitting Diode display (OLED). OLED displays are based on organic materials that emit light when electric currents excite them. For the present application, it is sufficient to mention that OLED displays whose organic material is made of conjugated polymers (referred to as PLED displays) can be manufactured by ejecting a solution of the polymer through tiny nozzles such as available in ink jet mechanisms.

Based on the emissive nature of OLEDs, it has been attempted to apply these materials into applications where the nature of the display is static rather than dynamic. In saying this, within the context of the invention, the term “static” is meant to imply that the displayed image is constant and unvarying.

EP 1 351 303 to Eastman Kodak Company published Oct. 8, 2003 and entitled “Displaying selected images using an organic light-emitting display” discloses an organic light emitting display device and a method of fabrication thereof for displaying selected images from a plurality of images, each with one or more desired colors. The images may be static thereby avoiding the need for addressing.

The image is realized by a colored shape that is produced by OLED in the following way. First, an electrode, which can be an anode or cathode, is shaped on the substrate. Secondly, light emitting material designed to give a specific colored light associated with the shape of the electrode is deposited on the area occupied by the shape of the electrode, by spatial combination of minuscule areas of different colors, which when illuminated together will result in the desired specific coloring of the shaped electrode. In such an approach, the shaping of the electrode is the first and basic requirement.

By such means, there is a created a display of colored icons on a substrate, with each individual icon illuminated separately, and with each icon's shape pre-formed by patterning the electrode.

U.S. Pat. No. 6,501,218 (Duggal et al.) published Dec. 31, 2002 and entitled “Outdoor Electroluminescent Display Devices” describes an OLED display where the anode, cathode or both are patterned so that light will be emitted only in the region of patterned electrode.

U.S. Pat. No. 5,902,688 (Antoniadis et al.) published May 11, 1999 and entitled “Electroluminescent Display Device”, discloses an electroluminescent display device having anode, cathode, insulator and organic electroluminescent layers. A patterned insulating layer is interposed between the anode and the hole ejection layer or between the cathode and the electron ejecting luminescent layer. Such insulating layer may be made of photoresist epoxy material that can be patterned in production by exposure to UV light through a mask.

Where UV light strikes the photoresist, it will be “cured” (hardened) and the remaining, unexposed photoresist is washed away. This leaves a patterned insulated layer that inhibits emission of light in the patterned area, thus creating a display of complementary pattern to the non-insulated area.

U.S. Pat. No. 6,582,756 (Antoniadis et al.) published Jun. 24, 2003 and entitled “Method and apparatus for fabricating polymer-based electroluminescent displays” discloses a method for fabricating an electroluminescent display and the substrate and apparatus used therein. The display is preferably constructed on a pre-constructed substrate that includes a flexible base layer having a conducting surface on one side thereof. The substrate includes a plurality of wells defined by a barrier layer formed by mask, each well having an electrode layer connected electrically with the conducting surface.

In all of the above-mentioned patent publications, the result will be a display depicting either the area of discontinuation in the insulating layer, or the area of the patterned electrode. To the observer the visual impression is the same whether the patterned image is implemented as a “negative” in the case of insulating material or as a “positive” as in the case of a patterned electrode.

The creation of a patterned insulating layer or a patterned electrode requires usage of masks and multi-step processing, and the need to change masks if different patterns are to be used in different displays. Moreover, in the case that more than one color is to be used in different regions, such approaches are extremely difficult to use, or even impossible.

Furthermore, U.S. Pat. No. 5,902,688 requires full coating with expensive luminescent material, even when only a part of the coating is to be used actually.

OLED display panels which are based on light emitting polymers have a relatively simple multilayer structure as depicted in FIG. 1 and comprise:

1. A transparent glass or plastic material base layer 1.

2. A relatively transparent anode 2 made of Indium-Tin Oxide (ITO) which is deposited on the transparent layer by sputtering.

3. A hole ejection layer 3, formed of an ultra thin coat of “PEDOT” (polyethylenethioxythiophene) or similar material. Such layer can be made by spin coating, doctor blade coating or by ejection from ink jet mechanisms.

4. An electron ejection layer 4, which is the luminescent layer, made of conjugated polymers or phosphorilated conjugated polymers of a PPV or polyfluorene structures. For the sake of brevity these are shown in the figure and will be referred to as PPV.

5. A cathode 5 made of Ca, Au or Al deposited by sputtering on layer 4, or applied as a foil. This layer, as well as layer 4, does not need to be transparent

6. A sealing layer (not shown) that seals the other layers from water and oxygen.

The thickness of all layers combined can be sub-millimetric, and if plastic material is selected for the base, this type of flat panel display can be folded or made to conform to curved surfaces.

Most of the currently available PLED flat panel displays are structured to display dynamic images and have a multiplicity of addressable picture elements so that the display is changeable dynamically, up to the level where superb video images can be displayed.

U.S. Pat. No. 6,565,231 (R. S. Cok) published May 20, 2003 and entitled “OLED Area Illumination Lightning apparatus” discloses an electroluminescent display device having a substrate, anode, cathode, and organic electroluminescent layer and encapsulating cover. The two electrodes extend out of the device and are connected to a power source. This patent relates to multiple illuminated panels arranged in various 2D and 3D self standing illumination combinations. However, there is no suggestion to use more than one color per panel, or to incorporate the panels inside another device.

FIG. 13 of U.S. Pat. No. 6,565,231 illustrates lighting fixtures in which two more light sources are juxtaposed edge-to-edge in a common line so as to provide decorative channels similar to stained glass. This is another example of the use of OLEDs to produce static, as opposed to dynamic, images. Moreover, the approach taught by U.S. Pat. No. 6,565,231 is different from that shown in above-mentioned EP 1 351 303 since in the case of U.S. Pat. No. 6,565,231 there is no requirement to use electrodes that are pre-shaped to the desired display pattern. However, patterning is achieved using conventional lithographic techniques such as through-mask deposition, integral shadow masking, laser ablation and selective chemical vapor deposition. There is no suggestion to print the pattern using process printing techniques. Nor is there any suggestion to achieve the look of stained glass in a single OLED panel having multiple colored pixels that define a static image that requires only a single pair of electrodes.

Moreover, the light-emitting layer disclosed in U.S. Pat. No. 6,565,231 commonly consists of a host material doped with a guest compound or compounds where light emission comes primarily from the dopant and can be of any color. Alternatively, different colors may be achieved by providing colored, neutral density, or color conversion filters over the device. However, there is no suggestion to obtain different colors by the provision of triads of pixels corresponding to the three primary colors.

On the other hand, there is abundant information in the patent and other technical literature describing multicolor illuminated OLED devices in the form of active or passive display matrices that are structured as an X/Y matrix of pixels, each pixel containing one or more colored subpixels. But these, of course, require separate addressing and, in the case, of colored pixels require three address lines and three transistors per triad. Such OLED matrix devices are intended to be used as flat panel displays for TV, computer, PDA and cellular telephones displays and are structured to have a plurality of addressable picture elements so that the display is dynamically changeable in time, up to the level where superb video images can be displayed.

There are situations where a static unchanging image, in many cases having a multiplicity of colors, is required to be displayed. Examples are conventional still images as are displayed in advertising boards, museum artifacts and other similar exhibits, to name but a few. In such case, the provision of address lines and their associated circuitry is redundant and unnecessarily complex and expensive.

It would therefore be desirable to provide an OLED constructed to display a fixed, static pattern without the need to shape the anode and cathode, and without the need to cover the total area of the substrate with insulating layer. It would be a further advantage if the shapes and colors were formed by a similar process to process printing.

It would be a further advantage if the shapes and colors were formed by a process identical to process printing.

### SUMMARY OF THE INVENTION

It is a principal object of the invention to use OLEDs for the display of fixed images.

It is another principal object of the invention to display fixed images using a pixelized display whose pixels are not addressable.

It is yet another principal object of the invention to use an OLED to display a fixed image by printing the image directly on to a substrate without any need for masks to protect areas of the substrate.

Further objects of the invention relate to the use of OLEDs for the display of fixed patterned images having one or more colors per display, inside tiles similar in size and shape to ceramic tiles and whose illuminated images preferably use patterned or pixelized displays whose patterns or pixels are not individually addressable.

Preferably, such tiles are of sufficient strength so that they can bear pressure of an amount that conventional tiles are designed to withstand in walls or floors, and permit easy incorporation into construction elements such as walls, floor and ceilings, including also into such structures that are paved by conventional ceramic tiles.

In accordance with a preferred embodiment, the functionality of the OLED containing tiles is maintained in structures that are subjected to the severity of the elements or to have them embedded in water in the walls or floors of swimming pools.

Yet a further object of the invention is to provide an OLED device which when illuminated by exciting current will give a visual experience of a stained glass window.

It is another object of the invention to use OLEDs for the display of fixed images that function as “self” illuminated greeting cards, using processes identical or similar to conventional printing on paper while permitting the supporting structure to be not only flat but also curved, so that they can be maintained in an upright position on flat horizontal surfaces. Preferably, the functionality of such greeting cards is enabled by activating it only on command.

To these ends, the invention discloses an OLED and a method of production that lends themselves to easy and cost saving design of a fixed patterned display. The patterning of the displayed image can be done differently for each individual display, as the manufacturing process is as simple as printing by ink jet on paper. The invention proposes a way of patterning that does not require addressing by row and columns or the individual addressing of pixels and requires very few electrodes, even as few as two.

Thus, according to a first aspect of the invention there is provided a method for creating a static image capable of self-illumination, said method comprising:

printing constituent pixels of said image using a light emitting ink on a layer of an organic light emitting diode (OLED) device so as to form a pattern whose contour is determined only by said pixels and does not require masking or pre-shaping of the layer; and

providing a cathode and an anode for applying voltage across the OLED.

According to a second aspect of the invention there is provided a device having a static image capable of self-illumination when activated, said device comprising:

constituent pixels of said image printed using a light emitting ink on a layer of an organic light emitting diode (OLED) device so as to form a pattern whose contour is determined only by said pixels and does not require masking or pre-shaping of the layer.

Such a display device does not require power consuming back light as required by Liquid Crystal Displays (LCDs), and can be battery operated in contrast to the high power required by a plasma discharge panel. Moreover, while the manufacturing process is kept very simple, as ink jet printing, the results of the printing are dramatically different where the printing ink is emissive rather than reflective. By utilizing the proposed principles of the invention, it also possible to control the tiniest detail of the emissive prints in a way similar to that used in reflective ink printing, such as dot size, color density and hue saturation, without resorting to complex patterning of the electrodes or to interpose patterned insulating layers. Thus, the flexible patterning of such a display according to the invention facilitates new applications, some of which are described below.

The present invention provides a process printing of organic light emitting solutions to create static images. In a preferred embodiment such printing is done by jetting solutions containing polyfluorenes or PPV through tiny nozzles, such as exist in ink jet printing devices. As noted above, ink jet mechanisms have been used before with OLED solutions but for a different purpose, namely to create dynamic displays where red, green and blue droplets are injected in orderly sequences to create addressable pixels. The present invention, while utilizing a similar ink jet ejecting technique, which is designed to create complex static images, is close to conventional process printing, which can also be done by ink jet mechanisms.

FIGS. 2a and 2b summarize the specific characteristics of, and the differences between, conventional process printing and that proposed by the present invention as will now be outlined in more detail.

According to the present invention, creating static images is achieved directly by ink jet printing of solutions of light emitting polyfluorenes or PPV, with one or more colors. To achieve a fully color image, red, green and blue can be quite satisfactory, but if there is desire to increase the color gamut, additional colors may be added.

H.W. Sands Corp. of the USA supply not only red, green and blue emitters that are used in dynamic displays, but also yellow, orange and blue/green emitters. Another company, American Dyes Sources of Canada, supply in addition to red, green and blue emitters, also orange, yellow and violet emitters. Using such emitters, alone or in combination and printing them in a fashion similar to conventional process printing, can allow printing of any colored pattern which is easily achieved by injecting the colored solutions of the emitters through tiny nozzles such as are used in ink jet printing.

Commonly available ink-jet printers print with so-called process colors. A set of four inks is used to reproduce most of the visible colors. These inks are transparent and when printed in thin layers they act as filters. White light passes through the ink, and is reflected from the white background, showing the color of the ink. These inks are called subtractive inks, since they subtract a part of the spectrum from white light. The common set used in printing is: Cyan, Magenta, Yellow and Black. The black ink is used to enhance dark areas.

The principle of operation of the subtractive inks dictates the pre-printing processes used in order to prepare images for printing. Images for conventional ink-jet printing are normally originated as RGB images from scanners, digital cameras or graphic software. The images consist of pixels, each having a certain color value. The first stage is to convert these images to CMYK files having four digital layers that when printed together with CMYK inks reproduce the original image. Nowadays this is a fully computerized process, involving complicated mathematical transformations.

The CMYK data may be manipulated in order to fine-tune the print quality. Various lookup tables are applied to the data in order to improve the print quality and overcome some of the limitations of the CMYK inks and the specific ink-jet head. Most ink-jet heads print with tiny droplets, which give fixed color intensity on the substrate. In order to produce different saturation of a desired color, the droplets making up the color are printed with varying frequency, i.e. the number of dots/mm² is changed in order to produce different saturations. Alternatively, the droplets may be printed in small groups each having different areas. The process of converting the full color image to an image of dots of varying frequency or size is called half-toning or screening.

A halftone file consists of the process colors separations, each as a bitmap (black and white) image. The bitmap images are further manipulated in order to make them suitable for printing with specific ink-jet heads. The image may be pre-processed by screening and dithering as in conventional printing. Moreover, the image may be adjusted using known printing techniques to allow for compensation and correction of the image. Such correction can include corrections to color balance, saturation, color linearization, overlapping and so on. Although these techniques are well known per se, it is not believed that their application has been proposed in the art of OLEDs.

Printing with OLED materials, as proposed in the present invention, is similar, but not identical.

Thus, as distinct from process printing using conventional inks, in the present invention:

1. The OLED “inks” are neither transparent nor reflective; they are emitters.

2. The basic colors of the OLEDS are RGB, not CMY 3. Color tones may be created either by printing dots side by side, or by overlapping them. In each case, unlike for CMYK inks, the combined colors result from electronic interactions as well as optical principles.

4. The color transformations either from conventional RGB to the OLED colors or for each OLED color “separation”, are totally different from the CMYK transformations.

5. Owing to the nature of the OLED materials, screening processes strongly affect the final colors of the image. This phenomenon is almost nonexistent in CMYK printing.

6. Owing to the interactions between the printed droplets, nozzle-mapping is also different from CMYK nozzle-mapping.

7. The complete layer can easily be printed such that areas not corresponding to the pattern are “filled” with any neutral color that serves as background against which the pattern stands out. For example, the background areas can be printed using an ink formed of a material similar in conductive properties to the colored inks but having no light emissive properties, and therefore appearing black. However, by the same token, any other neutral color can be used. This prevents shorting between the PEDOT layer and the cathode of the OLED which would otherwise occur; although it is not required if the electrodes are pre-shaped so as to avoid the background area.

The present invention addresses such differences by incorporating software that addresses the above-mentioned unique characteristics of OLED emitters. Once the software for a specific static image derived from an RGB scan of the image design is readied, the printing process proposed by the present invention is simpler than the prior art of creating colored static images, as the image is created simply by ejecting solutions of colored OLED emitters, such ejection being done under software control.

As each solution is ejected from a dedicated nozzle, or dedicated multi nozzle device, the software will command all the desired attributes of the process such as size of the drops and their positioning on the PEDOT layer, The process handles the operation of all jetting mechanism of all colored solutions of OLED emitters, so that the end result will be a colored OLED static image fitting the basic desired design.

The above description shows that there are essential differences between the conventional ink jet printing process using reflective colors and the printing process according to the invention using emissive colors. However, it is emphasized that the invention principally resides not in these technical differences but in the recognition that a static image can be patterned directly on the PEDOT layer or cathode of an OLED by printing the pixels forming the image directly using ink jet or other process printing using PPV light emissive ink. Since the pattern is static, such an approach obviates the need for separate address lines and actuation electronics for each pixel; does not require that the pixels be aligned with pre-formed electronics. Moreover, such an approach allows those areas of the pattern layer that bear no image (i.e. corresponding to un-patterned background) to be printed with any desired neutral color. Since the whole of the pattern is thereby covered with ink formed of non-conductive material, this avoids the need for pre-shaping of the electrodes, which otherwise is required to ensure that empty areas not occupied by the pattern do not short-circuit between adjacent layers of the OLED.

### BRIEF DESCRIPTION OF THE DRAWINGS

In order to understand the invention and to see how it may be carried out in practice, a preferred embodiment will now be described, by way of non-limiting example only, with reference to the accompanying drawings, in which:

FIG. 1 is a pictorial representation of a prior art OLED display panel based on light emitting polymers having a relatively simple multilayer structure;

FIGS. 2a and 2b are flow chart showing respectively the principal operations required for ink jet printing with conventional light reflecting inks and with light emitting inks according to the invention;

FIG. 3 depicts a pattern in the form of the letter “A” that is obtained by printing of the luminescent material;

FIG. 4 is a pictorial representation showing creation within a fixed printed pattern also sub-patterns of illumination by controlling at any point the thickness of the PPV layer;

FIG. 5 shows pictorially provision of gradual illumination using screening;

FIGS. 6, 7, 8 and 9 are cross sections of a tile having a pattern formed by ink jet printing using OLED technology according to various embodiments;

FIG. 10 is an exploded pictorial representation showing construction of a translucent OLED device according to the invention;

FIG. 11 is a schematic representation showing patterning of the OLED device shown in FIG. 10 so as to produce the effect of stained glass;

FIG. 12 is a schematic representation showing patterning of the OLED device shown in FIG. 11 wherein different colored areas are demarcated by heavy black lines;

FIG. 13 is schematic representation of a greeting card having an illuminated pattern formed by ink jet printing using OLED technology according to the invention; and

FIG. 14 shows a detail of the card depicted in FIG. 13 in its closed state.

### DETAILED DESCRIPTION OF EXEMPLARY EMBODIMENTS

Essentially, the invention proposes the use of PLEDs for the display of fixed images permitting a very simple addressing scheme in comparison to conventional pixelized displays.

As a result, the invention achieves the following advantages:

1. Different patterns can be created on different display elements under software control.

2. In the case where the pattern to be viewed does not occupy all the display area, the luminescent material in the non-functional areas is saved.

3. Multi-color complex images can be created and viewed without the need to use a multiplicity of electrodes or electronic addressing elements, as long as the image is fixed.

The invention relies on the utilization of ink jet technology to print patterns of the electroluminescent material (“layer 4” above) as desired to depict a clear active light images. There is need for only one anode and one cathode that cover the total area of the display. There is also a continuous coating with the hole injection layer, so the patterning can be made just by selective coating of the luminescent OLED material.

This can be achieved by injecting the luminescent material (PPV) using an ink jet mechanism. The PPV is dissolved in a solution with low enough viscosity to make it injectable by an ink jet mechanism. Suitable solvents are, for example, Anisol or Benzene-based. However, as it dissolves in aggressive solvents, most ink jet mechanisms are not suitable for this purpose. The inventors have found an ink jet mechanism that is made solely of glass and silicon, and where instead of glues, electronic bonding of the parts is employed, to be suitable. Ink jet mechanisms employed to carry out the invention should be such that they will not be damaged by, or contaminate, the PPV solution. It has been found that these desiderata are met by an ink jet mechanism made of electronically bonded silicon and glass such as PL-128 of Industrial Ink Jet Technology of Israel.

Using a suitable ink jet mechanism, a pattern composed of the electroluminescent layer can be quickly achieved. As each single display is individually printed, patterns can be the same or different on different displays, and this is achieved by software control of the print. The displays are activated electrically just by passing current between the continuous cathode and the continuous anode of the display.

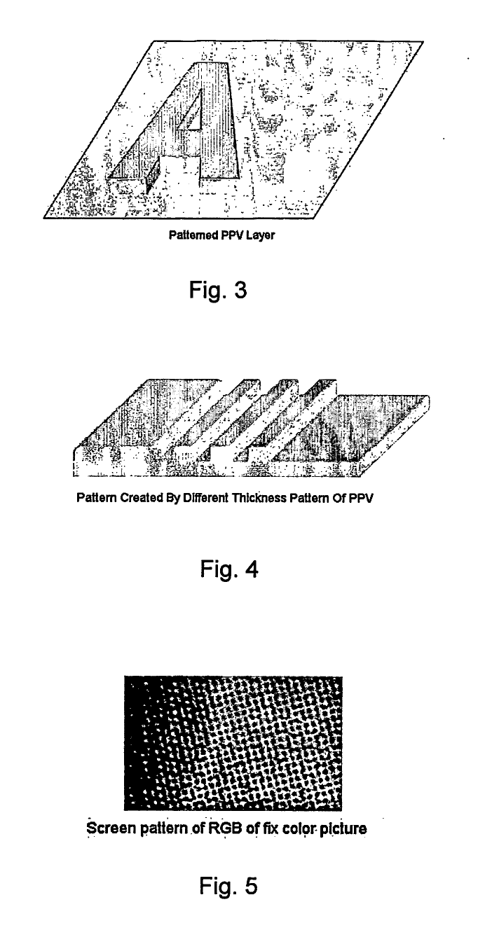

FIG. 3 depicts a pattern in the form of the letter “A” that is obtained by printing of the luminescent material.

Having a micro jetting mechanism with a resolution of 300 or 600 dpi and drops of a several tens or even only a few pico-liters, it is possible not only to simply inject the PPV solution but also to form a PPV layer with uniformity that will enable uniform color and brightness where needed. This is achieved by controlling the number and size of the droplets at each point.

Printing of the PPV material in a pattern which does not occupy the total area of the display results in areas where the PEDOT layer is in direct contact with the cathode. Therefore, in such areas the cathode and anode are separated only by the thin partially conductive PEDOT layer. As noted above, the invention avoids the resultant “shorting” by printing those areas that are not covered with light-emissive ink with a non conjugated polymer which acts as an insulator.

As depicted in FIG. 4, the ability to precisely control the thickness of the PPV luminescent layer makes it possible to create within the fixed printed pattern also sub-patterns of illumination. Wherever the layer is thin, the illumination is weaker (i.e. color saturation is less) than in the areas where the layer is thicker. This sub-patterning is achieved by enhancing the luminance and not by degrading it as described in UK patent application no. 2,384,115 where patterned UV light exposed through a mask is used to render some parts of the display less luminous. In the present invention the opposite occurs. The ink jet patterning is used to increase luminance by creating patterns with more of the luminous PPV materials.

Still another way to enable gradual illumination can be provided by using a screening and dithering method analogous to that used in conventional printing. The material is injected in form of discrete dots, and the level of illumination increases with the density of the dots. Thus, as shown in FIG. 5, the closer the dots (denser screen) the higher is the illumination.

### Novel Embodiments Enabled by the Invention

The invention allows not only the creation of illuminated signs and markers of uniform color as suggested by above-mentioned U.S. Pat. Nos. 5,902,688 and 6,501,218, but also creating signs and markers made of more than one color. This enables the use of different colors from different nozzles to create the desired patterns, as PPV with different colors are commercially available. The ink jetting mechanism may be made of several ink jet heads, each adapted to eject a respective differently colored PPV solution.

In principle, by using three separate ink jet heads having R, B G colors, respectively, it is possible also to print a pattern in the form of a colored picture with similar resolution and detail to that obtained by ink jet printing with C, M, Y and K printed on paper as is done conventionally. The difference is that the printed picture of the OLED is such that each printed dot does not reflect back colored light, but is luminous whenever a current is passed between the common cathode and common anode of the display.

Such a picture is “fixed” and is not dynamically changeable as in a matrix display. This difference is due to the fact that only two non-addressable electrodes are required in the invention as opposed to the multiple rows and columns of electrodes required in an active matrix display; nor is a separate transistor required for each pixel as in an active matrix display. Furthermore, no software and drivers to actuate the display of the invention are needed, in contrast to complex software and multiple drivers which are required by matrix type OLED displays.

Thus in such cases where the depicted image on the display is static and fixed a priori, the device of the invention is to be preferred over the conventional matrix activated OLED display owing to its simplicity and lower cost.

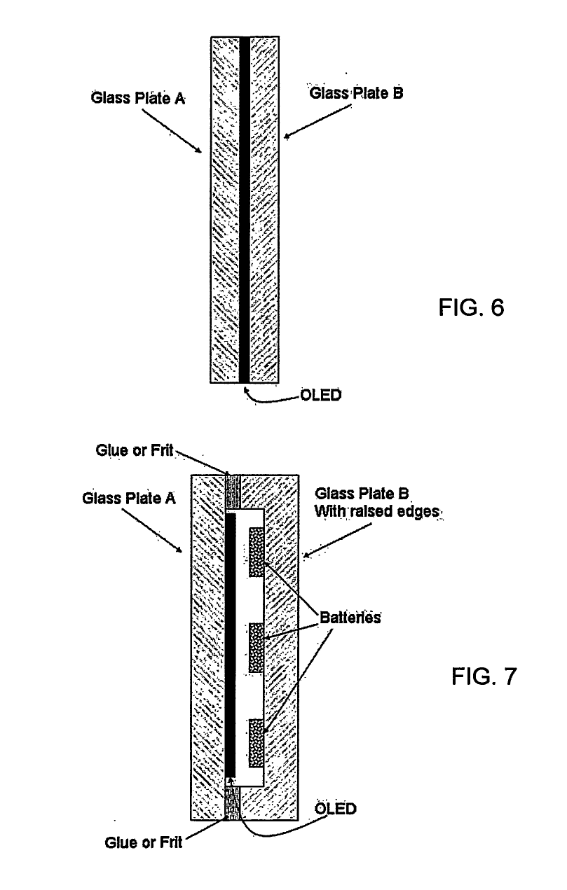

This aspect of the invention can be exploited in novel products including framed or unframed self illuminated static pictures and self illuminated greeting cards which can be manufactured individually or in bulk, all of which are enabled by a digitally controlled method of printing the luminous “ink” without the need to address selectively the picture elements. Examples of such applications are described below with particular reference to FIGS. 6 to 14 of the drawings.

While the invention has been described with particular regard to the use of ink jet technology to produce a fixed image on an OLED display, it is to be understood that other printing techniques may be used provided that each pixel of the resultant picture may be controlled to have the precise color composition, i.e. R, G, B balance so that when voltage is applied between the composite anode and cathode, each pixel will emit light of the desired color. Thus, appropriate printing techniques may also include color offset printing, for example.

It is also noted that, although the invention has been described with particular regard to printing the pattern on the PEDOT layer or the cathode of the OLED, this is because it has been found that printing the pattern on these layers is particularly effective. However, the invention embraces also OLED devices where the pattern is printed on other layers of the OLED.

Having described the principles in accordance with which an OLED device may be constructed using ink jet printing of colored pixels, there will now be described some commercial applications of such technique to form products displaying a fixed, static pattern using light emitting inks that form a patterned insulating PPV layer of an OLED that is equipped with only two electrodes. The commercial value of the applications that will now be described resides in their using light transmitting inks and pixels that are activated using a single cathode and anode and do not require separate addressing, thus obviating the need for separate transistors that are required in conventional OLEDs having dynamic displays. Moreover, only two electrodes are required even when the pattern includes colors formed from triads of R, G and B colored pixels. This represents a significant saving in complexity and cost compared with conventional techniques where all three pixels of each triad require their own transistor and addressing line.

In saying this, the patterns in the applications that will now be described are also amenable to being implemented using other techniques and therefore while their construction will be described with regard to the use of ink jet printing, it is to be understood that the patterns may also be constructed using conventional techniques.

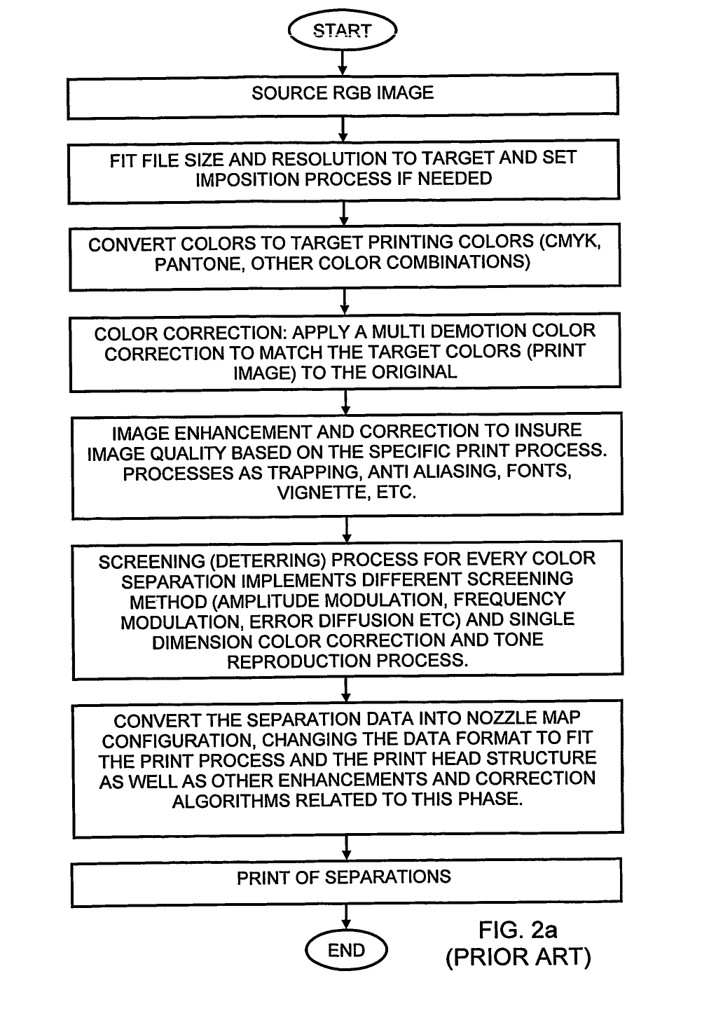

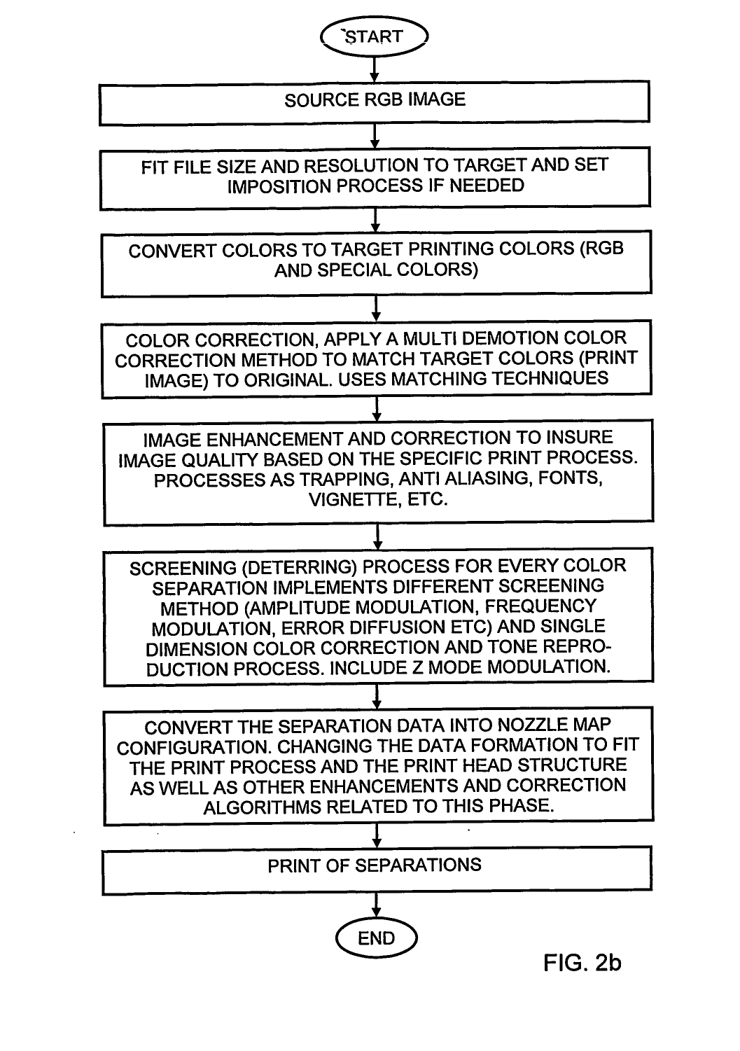

Thus, referring to FIGS. 6 to 9, a fixed image of an OLED display prepared according to invention as described above with reference to FIGS. 2a to 5, is executed on a glass plate A with a sufficient thickness to withstand the pressure that can be applied to the tile. This is a principally a function of the position of the tile i.e. whether it is mounted on a wall or in a floor. Once the OLED display is sealed, the glass plate A is glued or cemented by glass frit to another plate B which is made of glass, cement, concrete, metal or plastic such as ABS or polycarbonate of a sufficient thickness according to the external pressure tolerance of the tile. As the standard thickness of ceramic tiles is 9 mm, it will be understood by those skilled in the art in the light of the foregoing description that it is possible to create the tiles of sufficient strength to allow them to be installed not only in walls covered by tiles but also in floors.

The invention is not limited to tiles that are adapted to substitute for regular ceramic tiles and are therefore are of similar thickness, but may also be applied to self standing devices whose thickness can be smaller or larger than 9 mm.

FIG. 6 is a cross section of the tile device in its basic embodiment showing the glass plates A and B and the OLED sandwiched between them. The two wires which are connected respectively to the anode and to the cathode of the OLED are not shown.

The assembly of glass plate A to back plate B is done in a manner that the OLED printed surface of glass plate A is positioned against one of the surfaces of back plate B. In this way the imaged OLED is sandwiched between the two plates and can be seen through the transparent glass plate A.

If glue is used it can be spread over the outer insulating layer of the OLED on glass plate A, which can be compatible with glues such as acrylic based glue. Then the second plate, B, is cemented to the glue. In this way the two plates constitute a sandwich with the OLED in the middle. The cathode and anode of the OLED are each connected to a respective wire, parts of which are left outside the device prior to gluing for allowing connection to a power source.

FIG. 7 is a cross section of a second embodiment, wherein the plate B has raised narrow edges along its periphery, and the OLED is not assembled over the total area of glass plate A, thus leaving some free area on the edges of glass plate A along its periphery. The two plates are then bonded together either by glue or by glass frit which is then melted and bonds the two plates together. In this embodiment a space is formed between the two plates. This empty space is utilized for containing the power source of the OLED internally in the tile in the form of flat thin batteries. In such case the wires soldered to the anode and cathode remain inside the device.

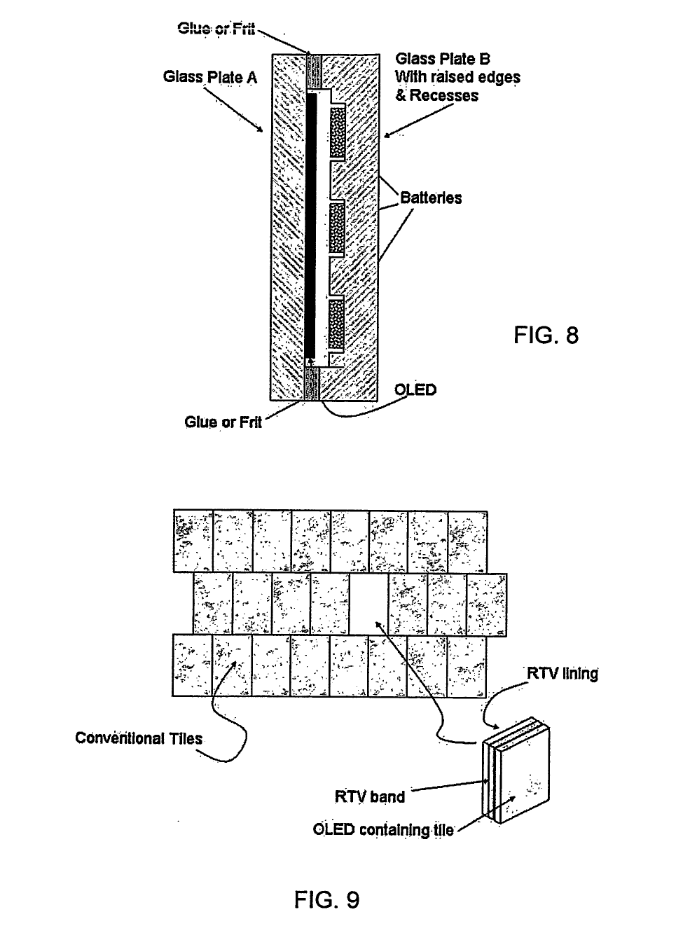

FIG. 8 is a cross section of a third embodiment, similar to the second, wherein the glass plate B has one or more internal recesses built into it for accommodating the batteries therein.

As shown in FIG. 9, the illuminated tile as described and illustrated in FIGS. 6 to 8 can be embedded smoothly into existing types of paving elements. For example, it may also include means that enable it to be inserted into floors, walls or ceilings which are covered with either conventional tiles or other tiles according to the invention. To this end, according to one embodiment the back of the OLED-containing tile as well as its sides are mounted with flat, thin layers of elastic material such as RTV, and the size of the device is kept very close to that of the surrounding tiles, being made of ceramic, marble, glass or mosaic or any other type of decorative tiles. When manufactured in this way, the tile of the invention can be inserted into the space allocated by gentle force and it can be retained without using cement.

The manner in which the tiles of the invention are fitted into a surrounding framework of other tiles, made of ceramics, stone or glass is not limited to the use of RTV. For example, the fittings can be made of various other materials such as metal or plastic, and the selection of fitting material can be determined by engineering and architectural needs.

While the above description of the invention relates to flat tiles, it is not limited only to such. The invention also embraces curved tiles when glass plates A and B are manufactured, for example by molding, as curved plates with suitable curvatures that will allow them to fit together to devices of the same geometrical nature.

The activation of the OLED device enclosed in the tile of the invention can be from any switching element in the case that the device receives power from an external source. In the case that both the OLED device and its power source, e.g. batteries are enclosed inside the tile, activation of the OLED, i.e. switching on its connection to the power source, can be achieved by various means such as electromagnetic or RF circuits, or by photo sensors or pressure sensors. The selection of the type of the switching circuit can be determined according to the specific use of the tile and its accessibility.

In use, the OLED self illuminating tile as described above with reference to FIGS. 6 to 9 can serve first as a light source panel embedded into a surface covered by conventional tiles. It is of sufficient strength to serve even on floors. It is also have its own enclosed power source and is therefore an improvement over hitherto-proposed illuminating panels having neither the resilience of the tiles of the invention, nor their own power source.

More important, the tile according to the invention benefits from the decorative features of a patterned or pixelated OLED having only two electrodes. This renders the tile of the invention more suitable to tile covered surfaces, most of which have decorative functions.

Using patterned OLED devices enclosed in a tile of this type can be very useful in the creation of illuminated emergency or warning signs, as the signs are well protected, have their own embedded power source and are visible both in daylight and dark conditions.

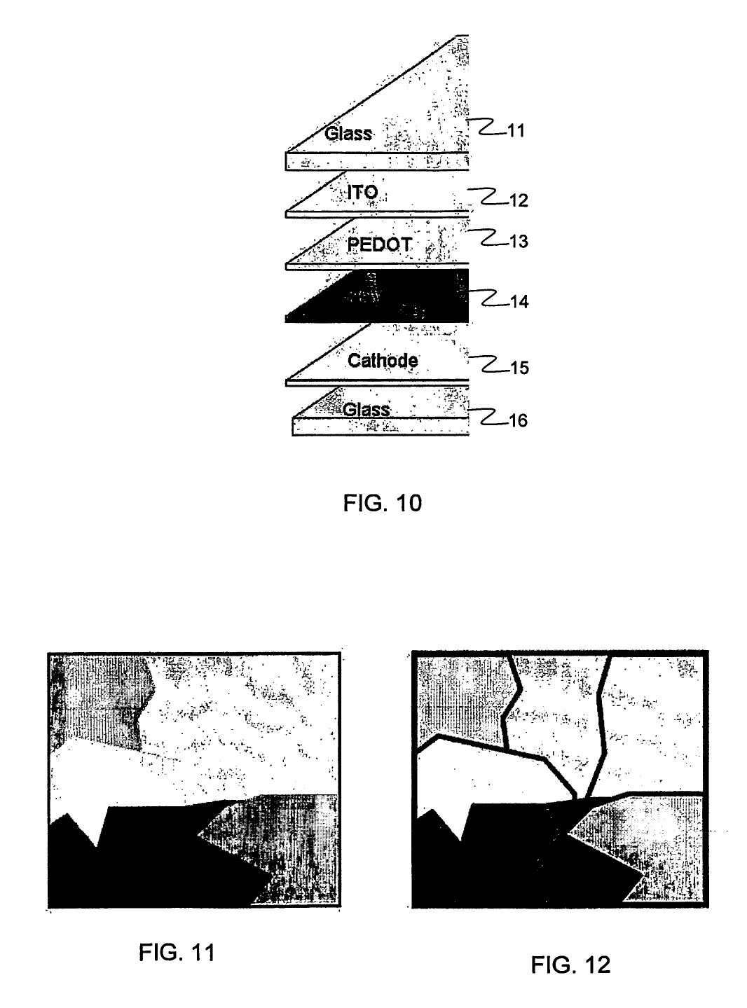

Referring now to FIGS. 10 to 12, there will be described a second application of a static colored pattern that may be applied to an OLED, using process printing such as ink jet technology for example, to resemble the visual effects of traditional stained glass windows. When day light in sufficient amount is available, no current is passed through the device, and the tinted luminescent layer then acts so that, in accordance with one embodiment, the device is substantially transparent. In use of such an embodiment, the OLED pattern may be made to resemble the visual effects of a traditional stained glass window to which the pattern of the OLED is precisely matched both in contour and color. The device is disposed in front of the traditional stained glass window so that the patterns of both are in proper alignment.

When no voltage is applied to the OLED device, it remains substantially transparent and the traditional stained glass window is thus visible through the OLED device. When voltage is applied to the OLED device, the pattern of the simulated stained glass window emits light and so is visible. If this is done at night or in low ambient daylight conditions, then the traditional stained glass window will be dark but on whichever side of the traditional stained glass window the OLED device is placed, the pattern will be illuminated thus giving the effect of back lighting through the traditional stained glass window. In order to equalize as much as possible the visual appearances during day and night, the voltage applied to the device may be controlled.

According to another embodiment, the OLED device is not transparent. In this case, the OLED pattern will be visible only when voltage is applied to the OLED device. Unless this is done, it will be opaque and even if it is mounted in registration with a traditional stained glass window, the pattern of the traditional stained glass window will not be visible. Thus, such an embodiment may be used to substitute for the traditional stained glass window, in which case there is no requirement for precise matching of the patterns of the traditional stained glass window and of the OLED device.

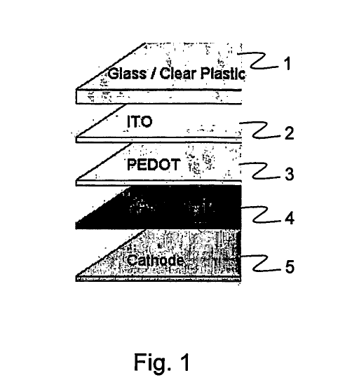

FIG. 10 shows schematically the multilayer structure of a transparent stained glass OLED panel according to the above-mentioned first embodiment. The OLED is constructed as described above with reference to FIG. 1, comprising a transparent glass or plastic material base layer 11, a relatively transparent anode 12 made of Indium-Tin Oxide (ITO) which is deposited on the transparent layer 11 by sputtering. A hole ejection layer 13 is formed of an ultra thin coat of “PEDOT” (polyethylenethioxythiophene) or similar material made by spin coating, doctor blade coating or by ejection from ink jet mechanisms. An electron ejection layer 14, which is the luminescent layer, is made of PPV. A cathode 15 made of Ca, Au or Al is deposited by sputtering on the PPV layer 14, or applied as a foil. This layer, as well as the PPV layer 14, does not need to be transparent. Finally, a transparent sealing layer 16, such as glass, is applied for sealing the other layers from water and oxygen.

FIG. 11 shows a pattern of contiguous colored areas that is printed with light emissive ink on the PPV layer 14, using ink jet technology for example, so that when voltage is applied across the anode 11 and the cathode 15 the colored areas emit light in accordance with the color of the illuminated pixels. The level of luminosity is a non-linear function of the voltage applied across the anode and cathode. This can be controlled manually, or via a programmable servo mechanism by connecting the two electrodes to the power source through a voltage level controller (not shown). The controller receives an input from a photo sensor that measures the ambient light-level, and whose input serves to increase or decrease the voltage to the desired level by firmware included in the controller.

FIG. 12 shows an alternative embodiment, which simulates ancient stained glass art where colored glass pieces were held together by lead strips. In the invention, the lead joints are simulated by heavy black lines printed with black resin using ink jet or lithographic processes so as to overlap respective common boundaries between contiguous colored areas.

Thus, the invention provides an OLED device which, when illuminated by exciting current, will give a visual experience of a stained glass window. The colored pattern can be achieved using ink jet printing techniques as described above with reference to FIGS. 2b to 5. However, it will be appreciated that the colored areas may be deposited using other techniques. The stained glass OLED device and pattern according to the invention as shown in FIGS. 10 to 12 is distinguished over hitherto-proposed effects, such as described in above-referenced U.S. Pat. No. 6,565,231, not only by the simplicity of printing the pattern but also by virtue of the colored areas being deposited on a single panel thus avoiding the need to juxtapose multiple panels edge to edge.

Using this approach to create a patterned OLED on a glass substrate that will fit into a window frame, the visual perception of a stained glass window can be achieved when voltage is applied across the two electrodes 11 and 15.

Yet another application of the OLED device according to the invention relates to greeting cards having a light-emissive decoration. Currently many decorative greeting cards are printed on thick paper sometime embossed by shiny foil or radiant colors, as it is desired that they will be very attractive and draw attention. Some companies such as Lumax of the Netherlands print their greeting cards on semi-transparent paper and supply them with a tea-light candle or bulb lamp holder. The card is mounted in the holder and back lit. These cards are produced by conventional printing techniques.

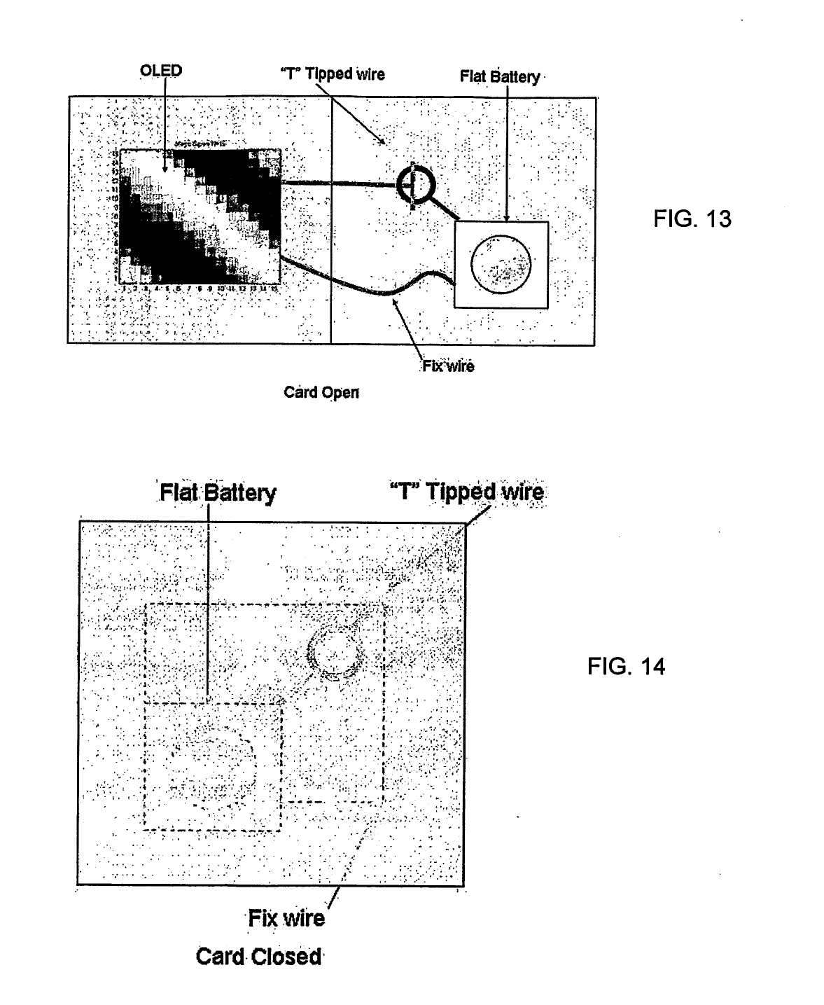

FIG. 13 shows schematically an open greeting card according to the invention. A decorative pattern formed by printing on the PPV layer of an OLED as described above is affixed to one side of the card and connected to a flat battery mounted on the other side thereof. One wire is connected from the anode of the OLED directly to the positive battery terminal, while the cathode of the OLED is connected to the negative battery terminal via a switch formed, for example, of a T-shaped tip that is stretched and pressed against a loop of wire connected to the battery, thus forming electrical contact.

FIG. 14 shows the card in the closed position, wherein the T-shaped tip is retracted, so that the battery circuit is incomplete and the OLED is inactive. When the card is opened, the T-shaped tip extends and contacts the loop, thereby completing the circuit and causing the OLED to be illuminated. It will be appreciated that the switch can just as effectively be connected between the anode of the OLED and the positive battery terminal.

The fixed image of the display is executed on thin transparent film that acts as the substrate. The thickness of such substrate can be as that of paper stock. However for practical purposes and appearance it is desired to use thickness of 200 gm paper stock or greater. The thickness of all other layers of the OLED is sub millimetric. Alternatively the OLED can be printed on thinner substrate which in turn is mounted on heavy stock paper.

The result is an OLED imaged pattern mounted in a “card” which can be mailed in an envelope. As long as the OLED is not powered only a flat dull colored non-discernible image can be seen. When powered up, the image appears clearly as an illuminated pattern having luminance intensity close to that of a CRT or LCD screen with vivid colors and high contrast. The OLED device can be made so that it will be automatically powered when taken out of the envelope by the recipient. This can be done using an actuation circuit that is sensitive to light for example. Such techniques are well known in the art.

The applications described above with reference to FIGS. 6 to 14 are clearly exemplary and are intended merely to illustrate the ease with which the principles of the invention can be commercialized to produce a wide variety of products having a static image that is formed using an OLED constructed according to the invention. Other applications will lend themselves to those of average skill in the relevant arts.

1. A method for creating a static image capable of self-illumination, said method comprising:
printing constituent pixels of said image using a light emitting ink on a layer of an organic light emitting diode (OLED) device so as to form a pattern whose contour is determined only by said pixels and does not require masking or pre-shaping of the layer; and
providing a cathode and an anode for applying voltage across the OLED.

2. The method according to claim 1, including:
generating half tone color separation masks each corresponding to a respective color component of said pixels and to a neutral background color;
printing the pixels corresponding to the color components using respective light emitting inks; and
printing the pixels corresponding to the neutral background color using an ink that is neither light emitting nor electrically conductive.

3. The method according to claim 1, further including activating a process printer so as to print said color components separately.

4. The method according to claim 1, wherein a single anode and a single cathode are provided for activating all of said pixels simultaneously thus avoiding a need for separate addressing of selected pixels.

5. The method according to claim 1, wherein said pixels are printed on a PEDOT layer or a cathode of the OLED.

6. The method according to claim 1, wherein the pixels are formed using different colored light emitting inks.

7. The method according to claim 1, wherein light saturation of selected pixels is varied by depositing a greater thickness of light emitting ink where higher saturation is required.

8. The method according to claim 1, wherein said pixels are printed using ink jet technology.

9. The method according to claim 1, further including processing the image as in conventional printing to effect compensation and/or adjustment of the image.

10. The method according to claim 1, wherein the processing includes pre-processing the image by screening and dithering.

11. The method according to claim 1, further including encapsulating the layer having said the pattern printed thereon within a device.

12. A device having a static image capable of self-illumination when activated, said device comprising:
constituent pixels of said image printed using a light emitting ink on a layer of an organic light emitting diode (OLED) device so as to form a pattern whose contour is determined only by said pixels and does not require pre-shaping of the layer.

13. The device according to claim 12, wherein pixels corresponding to a neutral background color are formed of an ink that is not light emitting.

14. The device according to claim 12, wherein pixels corresponding to a neutral background color are formed of an ink that is not electrically conductive.

15. The device according to claim 12, including a single anode and a single cathode for activating all of said pixels simultaneously without requiring separate addressing of selected pixels.

16. The device according to claim 12, wherein said pixels are printed on a PEDOT layer or a cathode of the OLED.

17. The device according to claim 12, wherein the pixels comprise different colored light emitting inks.

18. The device according to claim 12, wherein a thickness of selected ones of said pixels is varied according to a predetermined light saturation to be associated with said selected pixels.

19. The device according to claim 12, wherein said pixels are printed using ink jet technology.

20. The device according to claim 12, being a decorative tile.

21. The device according to claim 12, being a stained glass window having a single panel on which are printed contiguous areas of light emissive color.

22. The device according to claim 20, further including black lines printed so as to overlap a respective common boundaries between contiguous colored areas.

23. The device according to claim 12, being a greeting card.

24. A decorative tile having a pattern formed on a layer of an OLED.

25. A stained glass panel on which are deposited contiguous areas of light emissive color on a layer of an OLED.

26. The stained glass panel according to claim 24, further including black lines deposited so as to overlap a respective common boundaries between contiguous colored areas.

27. A greeting card having a pattern formed on a layer of an OLED.
